(19) United States
(12) Patent Application Publication
(10) Pub. No.: US 2015/0263125 A1
(43) Pub. Date: Sep. 17, 2015

(54) SEMICONDUCTOR MEMORY DEVICE

(71) Applicant: Kabushiki Kaisha Toshiba, Minato-ku (JP)

(72) Inventors: Masaya TERAI, Kawasaki (JP); Tsukasa TADA, Hachioji (JP); Hideyuki NISHIZAWA, Toshima (JP); Shigeki HATTORI, Kawasaki (JP); Koji ASAKAWA, Kawasaki (JP)

(73) Assignee: Kabushiki Kaisha Toshiba, Minato-ku (JP)

(21) Appl. No.: 14/641,746

(22) Filed: Mar. 9, 2015

(30) Foreign Application Priority Data
Mar. 17, 2014 (JP) 2014-054068

(51) Int. Cl. H01L 29/51; H01L 27/115; H01L 29/792

(52) U.S. Cl. CPC H01L 29/518; H01L 29/792; H01L 27/11582; H01L 29/513; H01L 29/517; H01L 27/11565

(57) ABSTRACT

A nonvolatile semiconductor memory device includes a semiconductor layer, a control gate electrode, and an organic molecular layer provided between the semiconductor layer and the control gate electrode and having an organic molecule including a porphyrin structure with oxymetal or chlorometal at the center.

### CROSS-REFERENCE TO RELATED APPLICATION

This application is based upon and claims the benefit of priority from Japanese Patent Application No. 2014-054068, filed on Mar. 17, 2014, the entire contents of which are incorporated herein by reference.

### FIELD

Embodiments described herein relate generally to semiconductor memory devices.

### BACKGROUND

Scaling-down the size of each memory cell is effective in realizing a lower bit cost and improving the memory performance of a nonvolatile semiconductor memory device. However, scaling down of a memory cell is becoming technically difficult.

In view of this, it has been proposed to use organic molecules for a charge storage layer. We can synthesize organic compounds with various molecular structures and substituents. Thus, desired electrochemical properties can be provided from their structures and substituents, and each structural unit is small. Therefore, scale-down of memory cell can be achieved.

For a nonvolatile semiconductor memory device using organic molecules in a charge storage layer, a further improvement in charge retention characteristics is desired.

### BRIEF DESCRIPTION OF THE DRAWINGS

FIG. 1 is a cross-sectional view of a memory cell portion of a nonvolatile semiconductor memory device in a first embodiment;

FIG. 2 is a circuit diagram of a memory cell array of the nonvolatile semiconductor memory device in the first embodiment;

FIG. 3 is an enlarged schematic diagram of an example of the memory cell portion of the nonvolatile semiconductor memory device in the first embodiment;

FIG. 4 is an enlarged schematic diagram of another example of the memory cell portion of the nonvolatile semiconductor memory device in the first embodiment;

FIG. 5 is a cross-sectional view of a memory cell portion of a nonvolatile semiconductor memory device in a second embodiment;

FIG. 6 is a cross-sectional view of a memory cell portion of a nonvolatile semiconductor memory device in a third embodiment;

FIG. 7 is a cross-sectional view of a memory cell portion of a nonvolatile semiconductor memory device in a fourth embodiment;

FIG. 8 is a three-dimensional conceptual diagram of a nonvolatile semiconductor memory device in a fifth embodiment;

FIG. 9 is an XY cross-sectional view of FIG. 8, and FIG. 10 is an XZ cross-sectional view of FIG. 8;

FIG. 11 is an XZ cross-sectional view of a nonvolatile semiconductor memory device in a sixth embodiment;

FIG. 12 is a graph showing results of capacitance measurement in Example 1;

FIG. 13 is a graph showing charge retention characteristics in Example 1, Comparative Example 1, and Comparative Example 2;

FIG. 14 is a graph showing charge retention ratios in Example 1, Comparative Example 1, and Comparative Example 2; and

FIG. 15 is a graph showing charge retention ratios in Example 2 and Comparative Example 3.

### DETAILED DESCRIPTION

A semiconductor memory device according to an embodiment includes: a semiconductor layer; a control gate electrode; and an organic molecular layer provided between the semiconductor layer and the control gate electrode, the organic molecular layer having an organic molecule including a molecular structure described by a molecular formula (1):

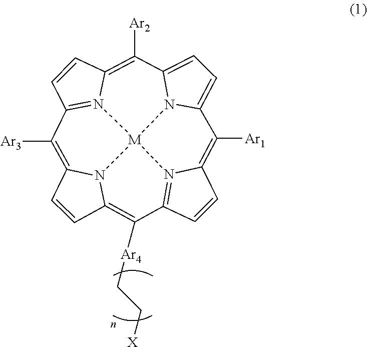

wherein M is oxymetal or chlorometal, Ar₁ to Ar₄ are each independently selected from among hydrogen, carbon, fluorine, a phenyl group, a phenyl halide group, an alkylphenyl group, an alkoxyphenyl group, a nitrated phenyl group, and a phenyl cyanide group, X is selected from among a silyl group, a phosphoryl group, a selenide group, a telluride group, an isocyanate group, an alkyl bromide group, an alkoxy group, and an ether group, and n is an integer more than or equal to zero.

In the description, the same or similar members are denoted by the same reference numerals, and redundant descriptions will not be made.

In the description, in order to express relative positional relationships between components or others, the words “upper” and “lower” are used. In the description, the words “upper” and “lower” are not necessarily intended to express relationships with the direction of gravity.

Hereinafter, embodiments will be described with reference to the drawings.

### First Embodiment

A nonvolatile semiconductor memory device in this embodiment includes a semiconductor layer, a control gate electrode, and an organic molecular layer provided between the semiconductor layer and the control gate electrode and having an organic molecule including a molecular structure described by the following molecular formula (1) or molecular formula (2):

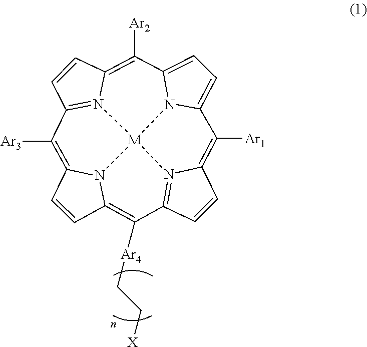

wherein M is oxymetal or chlorometal, Ar₁ to Ar₄ are each independently selected from among hydrogen, carbon, fluorine, a phenyl group, a phenyl halide group, an alkylphenyl group, an alkoxyphenyl group, a nitrated phenyl group, and a phenyl cyanide group, X is selected from among a silyl group, a phosphoryl group, a selenide group, a telluride group, an isocyanate group, an alkyl bromide group, an alkoxy group, and an ether group, and n is an integer more than or equal to zero, and

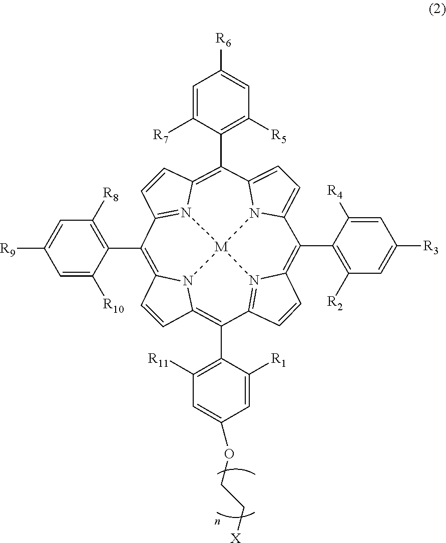

wherein M is oxymetal or chlorometal, R₁ to R₁₁ are each independently selected from hydrogen, a methyl group, halogen, an alkoxy group, a carboxy group, a cyano group, and a nitro group, X is selected from among a silyl group, a phosphoryl group, a selenide group, a telluride group, an isocyanate group, an alkyl bromide group, an alkoxy group, and an ether group, and n is an integer more than or equal to zero.

The device further includes a tunnel insulating film provided between the semiconductor layer and the organic molecular layer, and a block insulating film provided between the organic molecular layer and the control gate electrode.

The semiconductor memory device in this embodiment has the organic molecular layer constituting a charge storage layer between the tunnel insulating film and the block insulating film. The molecular structure of the organic molecules constituting the organic molecular layer contains a porphyrin structure having oxymetal or chlorometal at the center. The porphyrin structure is chemically adsorbed to the tunnel insulating film via a substituent.

The semiconductor memory device in this embodiment has the above configuration, thereby generating a dipole in a direction perpendicular to a porphyrin ring, and increasing reorientation energy of the organic molecules and the organic molecular layer. Thus, it facilitates retention of charges in the charge storage layer. Therefore, the charge retention characteristics (data retention characteristics) of the memory cell are improved.

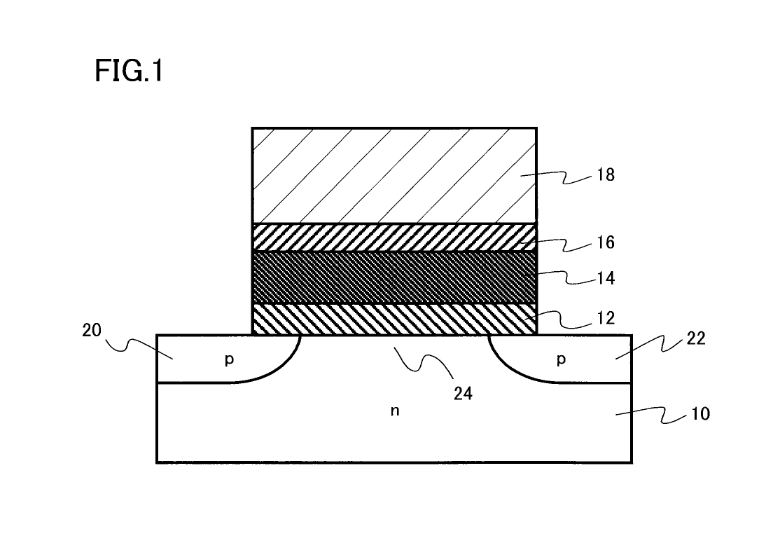

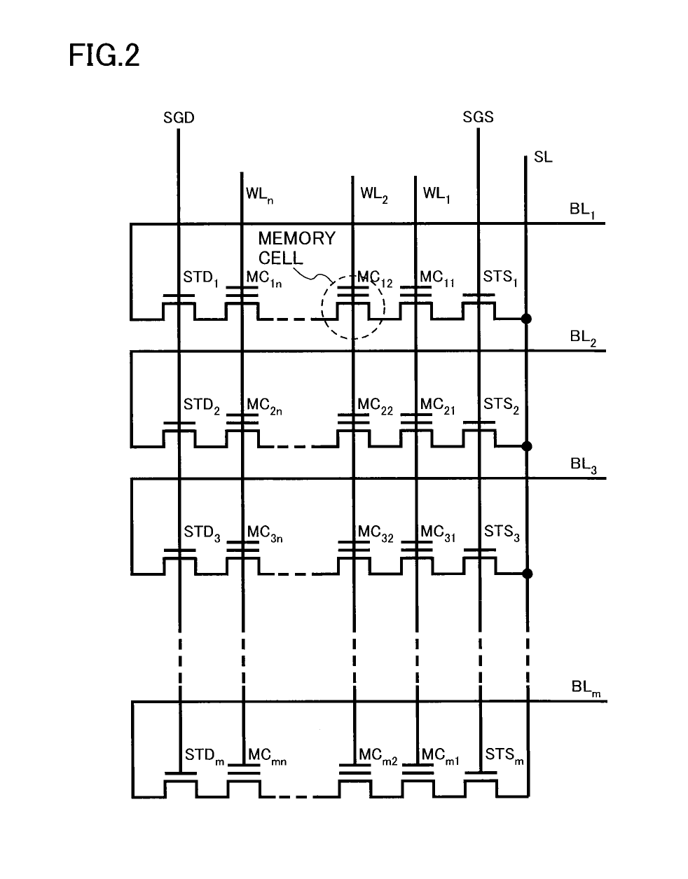

FIG. 1 is a cross-sectional view of a memory cell portion of a semiconductor memory device in this embodiment. FIG. 2 is a circuit diagram of a memory cell array of the semiconductor memory device in this embodiment. The nonvolatile semiconductor memory device in this embodiment is a NAND type nonvolatile semiconductor memory device.

As shown in FIG. 2, the memory cell array is composed of memory cell transistors MC₁₁ to MC₁ₙ, MC₂₁ to MC₂ₙ, . . . , MCₘ₁ to MC₁ₙ and that are m×n (m and n are integers) transistors having a floating gate structure, for example. In the memory cell array, these memory cell transistors are aligned in a column direction and a row direction, whereby the memory cell transistors are arranged in a matrix.

In the memory cell array, the memory cell transistors MC₁₁ to MC₁ₙ and select gate transistors STS₁ and STD₁ are connected in series, constituting a NAND string (memory string) as a cell unit, for example.

A drain region of the select gate transistor STS₁ for selecting the memory cell transistors MC₁₁ to MC₁ₙ is connected to a source region of the memory cell transistor MC₁₁ located at an end of the row of a group of memory cell transistors MC₁₁ to MC₁ₙ connected in series. A source region of the select gate transistor STD₁ for selecting the memory cell transistors MC₁₁ to MC₁ₙ is connected to a drain region of the memory cell transistor MC₁ₙ located at an end of the row of the group of memory cell transistors MC₁₁ to MC₁ₙ connected in series.

Selective gate transistors STS₂ to STSₘ, memory cell transistors MC₂₁ to MC₂ₙ, . . . , MCₘ₁ to MCₘₙ, and select gate transistors STD₂ to STDₘ are likewise connected in series separately, constituting NAND strings.

A common source line SL is connected to sources of the select gate transistors STS₁ to STSₘ. The memory cell transistors MC₁₁, MC₂₁, . . . , MCₘ₁, memory cell transistors MC₁₂, MC₂₂, . . . , MCₘ₂, . . . memory cell transistors MC₁ₙ, MC₂ₙ, . . . , MCₘₙ are connected with word lines WL₁ to WLₙ for controlling an operating voltage applied to the control gate electrodes, respectively.

A common select gate line SGS for the select gate transistors STS₁ to STSₘ and a common select gate line SGD for the select gate transistors STD₁ to STDₘ are also provided.

A peripheral circuit not shown is formed around the memory cell array in FIG. 2.

FIG. 1 shows a cross section of a memory cell in the memory cell array shown in FIG. 2, for example, a memory cell enclosed by a dotted line in FIG. 2. In this embodiment, description will be made of a case where a transistor of a memory cell is a p-type transistor using holes as carriers as an example.

The memory cell is formed on a semiconductor layer 10 of n-type silicon containing n-type impurities, for example. The memory cell includes a tunnel insulating film 12 on the silicon semiconductor layer 10, an organic molecular layer (charge storage layer) 14 on the tunnel insulating film 12, a block insulating film 16 on the charge storage layer 14, and a control gate electrode 18 on the block insulating film 16. A source region 20 and a drain region 22 are formed in the semiconductor layer 10 on opposite sides of the control gate electrode 18. A region in the semiconductor layer 10 below the control gate electrode 18 constitutes a channel region 24. The channel region 24 is interposed between the source region 20 and the drain region 22.

Here, the charge storage layer 14 has the function to actively store charges as memory cell information. When the memory cell can be written/erased, the tunnel insulating film 12 functions as an electron/hole transfer pathway between the channel region 24 in the semiconductor layer 10 and the charge storage layer 14 when the memory cell can be written/erased. At the time of reading or standing by, the tunnel insulating film 12 also has the function to of prevent electron/hole transfer between the channel region 24 and the charge storage layer 14 by its barrier height. The block insulating film 16 is a so-called interelectrode insulating layer, and has the function of blocking electron/hole flow between the charge storage layer 14 and the control gate electrode 18.

For the semiconductor layer 10, silicon germanide, germanium, a compound semiconductor, or the like other than silicon can be used.

The tunnel insulating film 12 is a silicon oxide (SiO₂) film, for example. The material of the tunnel insulating film 12 is not limited to a silicon oxide shown by example. Other insulating films can be used as appropriate.

The tunnel insulating film 12 may be a multi-layer film. For example, another material can be laid thereon to accelerate chemical bonding (chemical adsorption) of the organic molecules constituting the organic molecular layer 14 to the tunnel insulating film surface. For example, it may be an aluminum oxide.

The charge storage layer 14 is made of a monomolecular film, for example. The thickness of the charge storage layer 14 is desirably 20 nm or less in terms of miniaturization of the memory cell.

The block insulating film 16 is a metal oxide film, for example, a hafnium oxide. Other than the above-described hafnium oxide (HfO₂), an aluminum oxide (Al₂O₃) or the like, for example, may be used for the block insulating film 16.

The block insulating film 16 may be a single-layer film or a multi-layer film. The block insulating film 16 is a metal oxide film formed by an atomic layer deposition (ALD) method, for example.

The control gate electrode 18 is conductive polycrystalline silicon to which impurities have been introduced, for example. For the control gate electrode 18, any conductive material may be used. Other than the above-described polycrystalline silicon, for example, conductive amorphous silicon to which impurities have been introduced, or the like may be used for the control gate electrode 18. Alternatively, a metal, an alloy, a metal semiconductor compound, or the like may be used for the control gate electrode 18.

The source region 20 and the drain region 22 are formed by a p-type diffusion layer containing p-type impurities, for example.

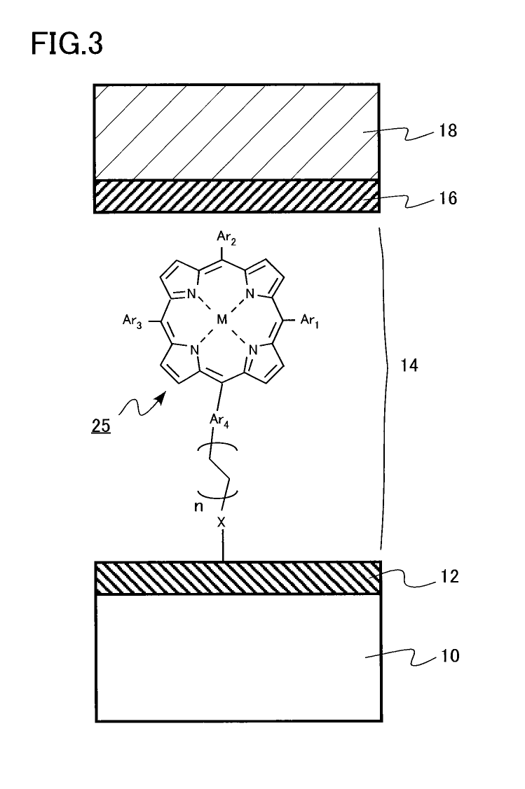

FIG. 3 is an enlarged schematic diagram of an example of the memory cell portion of the semiconductor memory device in this embodiment. It is a diagram showing details of the structure and adsorption form of an organic molecule used in the charge storage layer 14.

The charge storage layer 14 is composed of organic molecules (charge storage molecules) 25. The charge storage molecules 25 have the function to store charges to provide data on the memory cell.

The charge storage molecule 25 in the memory cell shown in FIG. 3 has a molecular structure described by the following molecular formula (1):

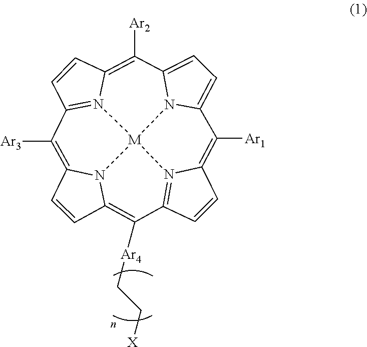

wherein M is oxymetal or chlorometal, Ar₁ to Ar₄ are each independently selected from among hydrogen, carbon, fluorine, a phenyl group, a phenyl halide group, an alkylphenyl group, an alkoxyphenyl group, a nitrated phenyl group, and a phenyl cyanide group, X is selected from among a silyl group, a phosphoryl group, a selenide group, a telluride group, an isocyanate group, an alkyl bromide group, an alkoxy group, and an ether group, and n is an integer more than or equal to zero.

The charge storage molecule 25 in the memory cell shown in FIG. 3 has at least a porphyrin ring in its structure. Oxymetal or chlorometal is bonded to the porphyrin ring at the center. The charge storage molecule 25 is further chemically bonded (chemically adsorbed) to the tunnel insulating film 12 via a substituent X. The substituent X is a so-called linker.

Since the charge storage molecule 25 is chemically adsorbed at the substituent X, the charge storage layer 14 can be considered as an organic monomolecular film. The charge storage layer 14 is of the order of nanometers, and does not constitute a layer in some cases when viewed strictly. In the description, the word “layer” is defined as a reference to the case where the surface density of elements considered to constitute the layer is 10 to the twelfth square centimeters or more.

Ar₁ and Ar₃ in the molecular formula (1) are desirably identical substituents in terms of facilitating the production of the charge storage molecule 25.

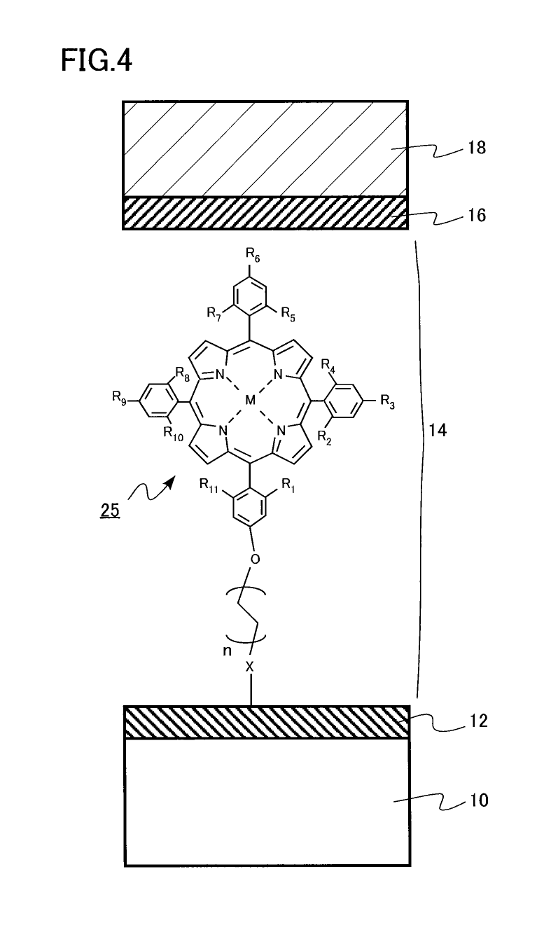

FIG. 4 is an enlarged schematic diagram of another example of the memory cell portion of the semiconductor memory device in this embodiment. It is a diagram showing details of the structure and adsorption form of an organic molecule used in the charge storage layer 14.

The charge storage molecule 25 in the memory cell shown in FIG. 4 has a molecular structure described by the following molecular formula (2):

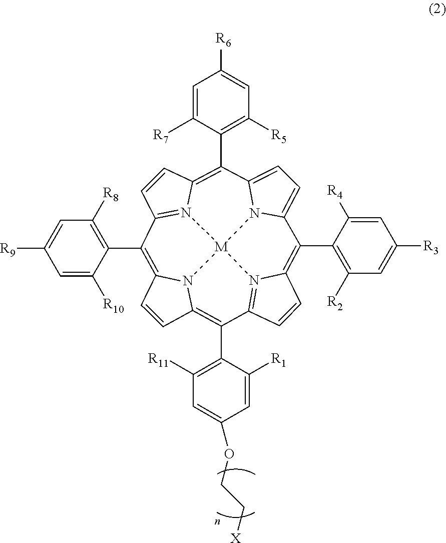

wherein M is oxymetal or chlorometal, R₁ to R₁₁ are each independently selected from hydrogen, a methyl group, halogen, an alkoxy group, a carboxy group, a cyano group, and a nitro group, X is selected from among a silyl group, a phosphoryl group, a selenide group, a telluride group, an isocyanate group, an alkyl bromide group, an alkoxy group, and an ether group, and n is an integer more than or equal to zero.

As shown in the molecular formula (2), the charge storage molecule 25 in the memory cell shown in FIG. 4 has a structure in which phenyl groups are bonded to a porphyrin ring. A structure having a phenyl group as in the molecular formula (2) allows for an increased variety of molecular designs by bonding a new substituent to the molecular structure. Further, by providing an ether group in a linker, it is possible to synthesize the charge storage molecule 25 easily.

The charge storage molecule 25 has the function to store charges by applying electric fields. It is desirable to use a porphyrin structure with high thermal durability in a charge storage portion. By oxymetal or chlorometal being used as an element group coordinated at the center of the porphyrin structure, the charge retention characteristics of memory cell that have the charge storage molecule 25 is improved.

As examples of oxymetal or chlorometal, more preferable specific examples include oxovanadium (V═O), oxytitanium (Ti═O), and chloroaluminum (Cl—Al).

The substituents X in the molecular formula (1) and the molecular formula (2) have the function of chemically adsorbing the charge storage molecules 25 on the tunnel insulating film 12 by chemical bonding for fixation. This allows the charge storage molecules 25 to be disposed on the tunnel insulating film 12 without being formed in multiple layers. Therefore, the charge storage molecules 25 act as the monomolecular charge storage layer with high thickness-uniformity, and achieve miniaturization of the memory cell.

Further, chemical adsorption of the charge storage molecules 25 on the tunnel insulating film 12 via the substituents X contributes improvement of thermal durability of the charge storage layer 14. Here, the improvement of thermal durability means increase of decomposition temperature, for example.

The substituent X is desirably consisted of a chemical functional group generally used for a self-assembled monolayer (SAM). For example, the substituent X is desirably selected from a silyl group, a phosphoryl group, a selenide group, a telluride group, an isocyanate group, an alkyl bromide group, an alkoxy group, and an ether group.

The charge storage molecules 25 can be detected by using a mass spectrometer (MS), a secondary ion mass spectrometer (SIMS), a nuclear magnetic resonator (NMR), an elemental analyzer, an infrared reflection absorption spectroscopy (IR-RAS), an X-ray fluorescence spectrometer (XRF), an X-ray photoelectron spectroscopy (XPS), an ultraviolet visible light spectrophotometer (UV-vis), a spectrofluorophotometer (FL) or the like.

When an insulating film such as a metal oxide is formed on the charge storage layer 14, it is analyzed while being cut off at the surface by a sputtering apparatus using argon ions or the like, for example. Alternatively, the charge storage layer 14 is dissolved and peeled simultaneously with the insulating film such as a metal oxide by a hydrofluoric acid solution. And the charge storage molecules 25 can be detected by analyzing that solution.

In the above-described method of analysis by cutting off the surface by a spattering apparatus or the like, the cutting method may be thermal treatment. In this case, a gas containing cut-off substances may be adsorbed by a different substance such as activated carbon, and then the different substance such as activated carbon on which the gas has been adsorbed may be analyzed for detection. In the above-described method of analyzing the solution, a solution containing substances may be subjected to decompression or thermal treatment for concentration.

In a memory cell writing operation in this embodiment, a voltage is applied between the control gate electrode 18 and the semiconductor layer 10 so that the control gate electrode 18 has a relatively negative voltage to store positive charges in the charge storage layer 14. When the control gate electrode 18 has a relatively negative voltage, an inversion layer is formed in the channel region 24 to store holes. The holes move through the tunnel insulating film 12 to be stored in the charge storage molecules in the charge storage layer 14.

In this state, the threshold voltage of the transistor of the memory cell is higher compared with a state where holes are not stored. That is, it is a state where the transistor is hard to turn on. This state is a state where data “0” is written.

In a data erasing operation, a voltage is applied between the control gate electrode 18 and the semiconductor layer 10 so that the control gate electrode 18 has a relatively positive voltage. An electric field between the control gate electrode 18 and the semiconductor layer 10 causes holes stored in the charge storage layer 14 to move through the tunnel insulating film 12 to be pulled out into the semiconductor layer 10.

In this state, the threshold voltage of the transistor of the memory cell is lower compared with the data “0” state. That is, it is a state where the transistor is easy to turn on. This state is data “1.”

When data is read, a voltage is applied between the source region 20 and the drain region 22. For example, in the data “0” state where holes are stored, the threshold voltage of the transistor is high, so that an inversion layer is not formed in the channel region 24 and current does not flow between the source and the drain.

On the other hand, in an erased state, that is, the data “1” state where charges are not stored, the threshold voltage of the transistor is low, so that an inversion layer is formed in the channel region 24 and current flows between the source and the drain. Thus, by detecting the amount of current of the transistor, it can be read whether it is data “0” or data “1.”

In a data verifying operation for verifying whether or not writing has been sufficiently done after performing the data writing operation, an operation similar to that in the reading operation is performed. A voltage is applied between the source region 20 and the drain region 22. When a desired current does not flow, the data writing operation is performed again.

The writing, erasing, and reading operations of the memory cell in this embodiment are performed as above for the function as a nonvolatile semiconductor memory device.

Next, the functions and effects of the semiconductor memory device in this embodiment will be described.

The charge storage molecules 25 are each chemically adsorbed on the tunnel insulating film 12 by chemical bonding, and form the uniform charge storage layer 14.

As described above, the charge storage molecules 25 have the function of storing charges injected from the channel region 24 through the tunnel insulating film 12.

The charge storage molecules 25 have the porphyrin structure. Charges injected from the channel region 24 through the tunnel insulating film 12 are mainly localized and stored in a porphyrin ring portion containing a center coordination substance. Stabilization of charged state means the reduction of electron transfer rate from a charge storing state to a neutral state. A transfer between the two states can be considered as follows when taken with Marcus theory.

An electron transfer rate coefficient K_{ET} from a charged state to a neutral state can be considered by the following equations:

$${k}_{ET} = \frac{2 π}{h} {V}_{CN}^{2} FC$$

$$FC = \frac{1}{\sqrt{4 π {λ}_{s} kT}} exp [ - \frac{{( Δ {G}^{0} + {λ}_{s} )}^{2}}{4 π {λ}_{s} kT} ]$$

wherein V_{CN} is an overlap integral of wave functions in the charged state and the neutral state, FC is the Franck-Condon factor, λₛ is reorganization energy, T is a temperature, ΔG⁰ is a difference in Gibbs free energy between the two states, and k is the Boltzmann constant.

Thus, in order to reduce the electron transfer rate coefficient K_{ET}, (1) reducing V_{CN}, (2) reducing ΔG⁰, and (3) increasing λₛ can be considered. To achieve (1), it is considered to reduce the electrical or physical interaction between a charge storage portion and a channel region, for example. To achieve (2), it is considered to control the levels of molecular orbitals in which charges are stored, for example.

The principal factor controlling λₛ is an electric field sensed by a molecule in the charged state. In particular, when a charged molecule has a dipole, an increase of its dipole is considered to cause an increase of λₛ. When one of the charge storage molecules 25 becomes in the charged state, and other surrounding charge storage molecules have large dipoles, λₛ is expected to be increased. Further, when a dipole near a portion in which charges are stored is generated, a further increase of λₛ can be expected.

As a result of repeated diligent studies based on this idea, it has been found to apply a structure having a dipole at a center coordination substance of a porphyrin ring to the charge storage molecules 25. In particular, by a structure having a center metal element at the center coordination substance and elements having large electronegativity bonded to the center metal element, a large dipole is generated outside the plane of the porphyrin ring. As the center coordination substance, oxymetal in which an oxygen atom is bonded to a metal atom, or a chlorometal in which a chlorine atom is bonded to a metal atom is preferable. More specifically, the center coordination substance is preferably oxovanadium (V═O), oxytitanium (Ti═O), or chloroaluminum (Al—Cl).

When zinc (Zn) is used as the center coordination substance as a representative example of using metal only, in addition to the above three as the center coordination substance of the same porphyrin derivative, the respective dipole moments of the derivatives determined by the basis function B3YP/6-31G (d) as calculated values are in Table 1.

TABLE 1

| | Dipole Moment | Dipole Moment in |
|---|---|---|
| | of Entire | Direction Perpendicular |
| | Structure | to Porphyrin ring plane |
| | (Debye) | (Debye) |
| Al—Cl Porphyrin Derivative | 3.350 | 3.349 |
| Ti═O Porphyrin Derivative | 2.551 | 2.550 |
| V═O Porphyrin Derivative | 2.022 | 2.02 |
| Zn Porphyrin Derivative | 0.042 | 0 |

As is clear when looking at Table 1, the derivatives having oxymetal or chlorometal as the center coordination substance have larger dipole moments compared with the derivative having a metal at the center. The directions of the dipole moments concentrate in a direction perpendicular to the porphyrin ring plane.

By thus using the charge storage molecules 25 in which oxymetal or chlorometal is used as a center coordination substance of a porphyrin structure, λₛ is increased, stabilizing the charge retaining state, and improving the charge retention characteristics of the memory cell.

Next, a method of manufacturing the semiconductor memory device in this embodiment will be described.

A method of manufacturing the nonvolatile semiconductor memory device in this embodiment includes forming a tunnel insulating film 12 on a semiconductor layer 10, forming a charge storage layer 14 on the tunnel insulating film 12, forming a block insulating film 16 on the charge storage layer 14, and forming a control gate electrode 18 on the block insulating film 16.

For example, the tunnel insulating film 12 is formed on the semiconductor layer 10 of single crystal silicon. When the tunnel insulating film 12 is a silicon oxide, it can be formed by thermal-oxidation method, for example.

Alternatively, the tunnel insulating film 12 may be formed by an apparatus for deposition such as ALD or sputtering.

When it is deposited, an insulating film after deposition is desirably annealed by a rapid thermal annealing (RTA) apparatus.

Next, the charge storage layer 14 is formed on the tunnel insulating film 12.

For forming the charge storage layer 14, the following method can be used, for example.

First, a surface of the tunnel insulating film 12 to be a base on which to form the charge storage layer 14 is cleaned. For the cleaning, for example, cleaning with a mixed solution of sulfuric acid and a hydrogen peroxide solution (the mixture ratio is 2:1, for example), or UV cleaning in which the insulating film surface is irradiated with ultraviolet light can be used.

Next, charge storage molecules 25 having the molecular structure of the molecular formula (1) or the molecular formula (2) are prepared. The cleaned surface of the tunnel insulating film 12 is immersed into a solution in which the charge storage molecules 25 are dissolved in a solvent. The substituents X are caused to react with the surface of the tunnel insulating film 12.

For the solvent, it is considered to use one in which organic molecules dissolve well, and organic solvents such as acetone, toluene, ethanol, methanol, hexane, cyclohexane, isopropyl alcohol, propylene glycol monomethyl ether acetate (PEGMA), and the like are considered. In the case of using charge storage molecules 25 which can dissolve in water, water can be used as the solvent. Mixtures of these can also be used as the solvent.

If the concentration of the charge storage molecules 25 to be dissolved in the solvent is too low, the immersion time becomes longer. If the concentration is too high, there is an increase in adsorbed unnecessary molecules that need to be removed by a rinsing operation. Therefore, it is preferable to adjust the concentration to an appropriate value. For example, the concentration is desirably about 0.01 to 100 mM.

A period of time for which the surface of the insulating film is immersed in the solution of the charge storage molecules 25 is desirably a period of time enough for sufficient reaction. Specifically, it is desirable to wait one minute or more.

In order to accelerate adsorption reaction between the substituents X and the tunnel insulating film 12 surface, a catalyst may be added. As a catalyst, for example, an acid or a base is sometimes selected to accelerate hydrolysis. When the amount of addition of the catalyst is too large, packing molecules self-react in the solvent, causing side reaction such as polymerization. Thus it is desirable to make it small. Desirably, it is 3% or less relative to the volume of the solution.

Thereafter, it is immersed in the solvent and rinsed using an ultrasonic cleaner. This operation is desirably performed at least two times or more with the solvent replaced with a new one so as to wash away an excessively physically adsorbed organic molecules.

Next, it is immersed in ethanol and rinsed using an ultrasonic cleaner likewise.

Thereafter, the solvent is removed by a nitrogen air gun or a spin coater from it, and drying is performed. As a result, the charge storage layer 14 composed of the charge storage molecules 25 is formed on the tunnel insulating film 12.

Thereafter, for example, a hafnium oxide film is deposited on the charge storage layer 14 to form the block insulating film 16.

The block insulating film 16 can be formed by an apparatus for deposition such as atomic layer deposition (ALD) or spattering. The deposition apparatus is desirably a low-damaging deposition apparatus with which the charge storage layer 14 formed by organic molecules is not degraded, and is desirably a thermal-type ALD apparatus, for example. It is desirable to anneal the insulating film after deposition by a rapid thermal annealing (RTA) apparatus, so as to increase the atom density in the film.

Thereafter, a polycrystalline silicon film doped with impurities is formed by a chemical vapor deposition (CVD) method, for example, to form the control gate electrode 18. Thereafter, Patterning is then performed on the stacked films, to form a gate electrode structure.

Thereafter, for example, p-type impurities are ion-implanted with the control gate electrode 18 as a mask to form the source region 20 and the drain region 22. Thus, the nonvolatile semiconductor memory device shown in FIG. 1 can be produced.

As above, according to this embodiment, by using the charge storage molecules 25 having the molecular structure of the molecular formula (1) or the molecular formula (2) for the charge storage layer 14, a nonvolatile semiconductor memory device having excellent charge retention characteristics can be realized.

### Second Embodiment

A nonvolatile semiconductor memory device in this embodiment is different from that in the first embodiment in that it does not include a tunnel insulating film, and a charge storage layer has the function of a tunnel insulating film. Hereinafter, contents overlapping with those in the first embodiment will not be described.

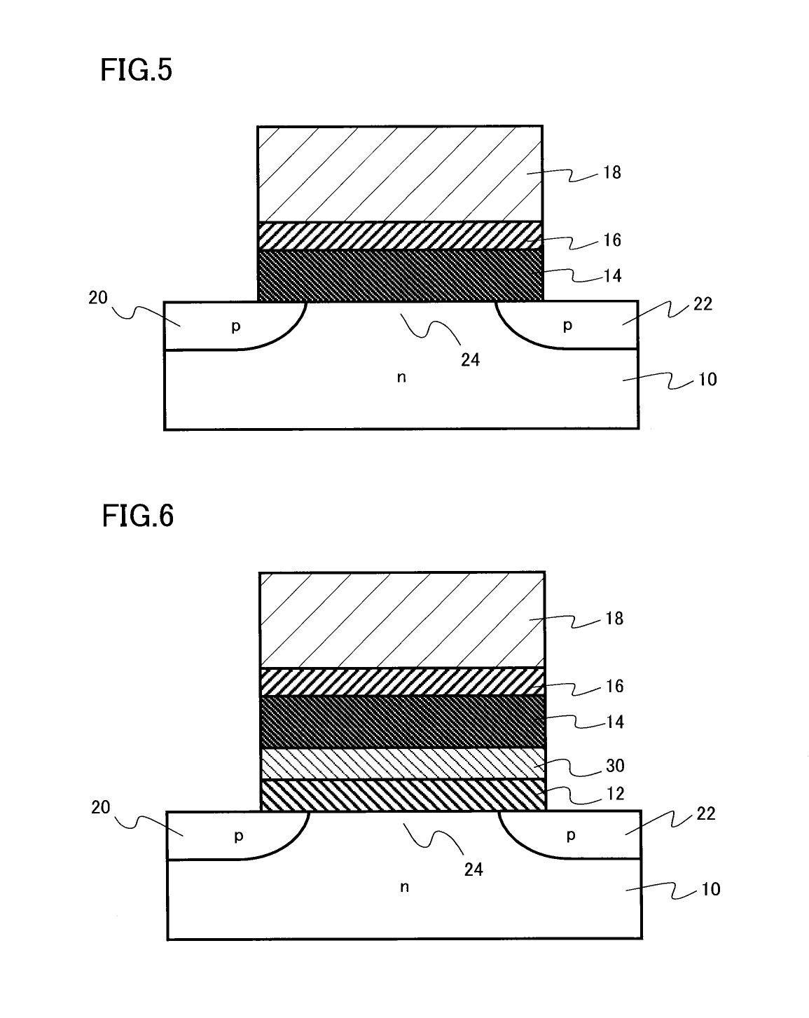

FIG. 5 is a cross-sectional view of a memory cell portion of the nonvolatile semiconductor memory device in this embodiment.

A memory cell is formed on a semiconductor layer 10 of n-type silicon containing n-type impurities, for example. The memory cell includes a charge storage layer 14 on the silicon semiconductor layer 10, a block insulating film 16 on the charge storage layer 14, and a control gate electrode 18 on the block insulating film 16. A source region 20 and a drain region 22 are formed in the semiconductor layer 10 on opposite sides of the control gate electrode 18. A region in the semiconductor layer 10 below the control gate electrode 18 constitutes a channel region 24. The channel region 24 is interposed between the source region 20 and the drain region 22.

In this embodiment, charge storage molecules 25 in the charge storage layer 14 also have the function of a tunnel insulating film. In this embodiment, the charge storage molecules 25 are directly chemically bonded to the semiconductor layer 10.

As in the first embodiment, the charge storage molecules 25 have the function of storing charges to provide data on the memory cell.

Alkyl chain portions of the charge storage molecules 25 develop the function of keeping insulation from the semiconductor layer 10. The charge storage molecules 25 are each an alkyl chain in which the carbon number (n) of an alkyl chain portion is six or more to thirty or less in the molecular formula (1) or the molecular formula (2), for example.

The carbon number of the alkyl chain is six or more to thirty or less, and is more desirably ten or more to twenty or less. This is because when it falls below the above range, insulation properties can be degraded and a self-assembled monolayer can be difficult to form. Also, this is because when it exceeds the above range, the film thickness can be large, resulting in difficulties in scaling-down.

A method of manufacturing the nonvolatile semiconductor memory device in this embodiment includes forming a charge storage layer 14 containing charge storage molecules 25 having the molecular structure of the molecular formula (1) or the molecular formula (2) on a semiconductor layer 10 by self-assembly, forming a block insulating film 16 on the charge storage layer 14, and forming a control gate electrode 18 on the block insulating film 16.

For example, the charge storage layer 14 is formed by self-assembly on the semiconductor layer (semiconductor substrate) 10 of single crystal silicon.

The method is identical to that in the first embodiment except that the charge storage layer 14 is directly formed on the semiconductor layer 10.

According to this embodiment, in place of an inorganic tunnel insulating film such as a metal oxide, the charge storage layer 14 implements the function of the tunnel insulating film. Therefore, the physical film thickness of the memory cell structure can be reduced. Thus, a nonvolatile semiconductor memory device with a minute memory cell can be realized.

Further, since the need to form an inorganic tunnel insulating film is eliminated, simplification of the manufacturing process can be achieved.

Further, it is also possible to cause the organic molecular layer 14 to have the function of the block insulating film by, for example, providing an alkyl chain or the like to the control gate electrode 18 side of the charge storage molecules 25 in the organic molecular layer 14, so as to provide a structure in which the inorganic block insulating film 16 is omitted.

### Third Embodiment

A nonvolatile semiconductor memory device in this embodiment is identical to that in the first embodiment except that a conductive layer is formed between a tunnel insulating film and a charge storage layer. Hereinafter, contents overlapping with those in the first embodiment will not be described.

FIG. 6 is a cross-sectional view of a memory cell portion of the nonvolatile semiconductor memory device in this embodiment.

A memory cell is formed on a semiconductor layer 10 of n-type silicon containing n-type impurities, for example. The memory cell includes a tunnel insulating film 12 on the silicon semiconductor layer 10, a conductive layer 30 on the tunnel insulating film 12, a charge storage layer 14 on the conductive layer 30, a block insulating film 16 on the charge storage layer 14, and a control gate electrode 18 on the block insulating film 16. A source region 20 and a drain region 22 are formed in the semiconductor layer 10 on opposite sides of the control gate electrode 18. A region in the semiconductor layer 10 below the control gate electrode 18 constitutes a channel region 24. The channel region 24 is interposed between the source region 20 and the drain region 22.

The conductive layer 30 has the function of uniformly dispersing charges to be stored in the charge storage layer 14. Therefore, the conductive layer 30 provides a uniform fixed charge distribution for the charge storage layer 14, realizing a stable operation. The conductive layer 30 also has the function of improving efficiency in reading and writing of charges stored in the charge storage layer 14.

The conductive layer 30 is, for example, a semiconductor film, a metal film, or a metal compound film. For example, amorphous silicon or polycrystalline silicon to which impurities have been introduced and conductivity has been imparted may be used.

In this embodiment, charge storage molecules 25 are bonded onto the conductive layer 30 by self-assembly. At this time, when the conductive layer 30 is doped-silicon, a substituent X of the charge storage molecules 25 is desirably a thiol group in terms of facilitating the bonding.

A method of manufacturing the nonvolatile semiconductor memory device in this embodiment includes forming a tunnel insulating film 12 on a semiconductor layer 10, forming a conductive layer 30 on the tunnel insulating film 12, forming a charge storage layer 14 containing charge storage molecules 25 having the molecular structure of the molecular formula (1) or the molecular formula (2) on the conductive layer 30, forming a block insulating film 16 on the charge storage layer 14 by an ALD method, and forming a control gate electrode 18 on the block insulating film 16.

The conductive layer 30 is formed on the tunnel insulating film 12 by a CVD method, an ALD method, a spattering method, or the like, for example. The charge storage layer 14 is formed on the conductive layer 30.

The method is identical to that in the first embodiment except that the tunnel insulating film 12 is formed on the semiconductor layer 10, and the charge storage layer 14 is formed on the conductive layer 30.

According to this embodiment, a nonvolatile semiconductor memory device stable in operation and excellent in reading and writing characteristics can be realized.

### Fourth Embodiment

A nonvolatile semiconductor memory device in this embodiment is identical to that in the first embodiment except that a transistor of a memory cell is an n-type transistor which uses electrons as carriers. Accordingly, contents overlapping with those in the first embodiment will not be described.

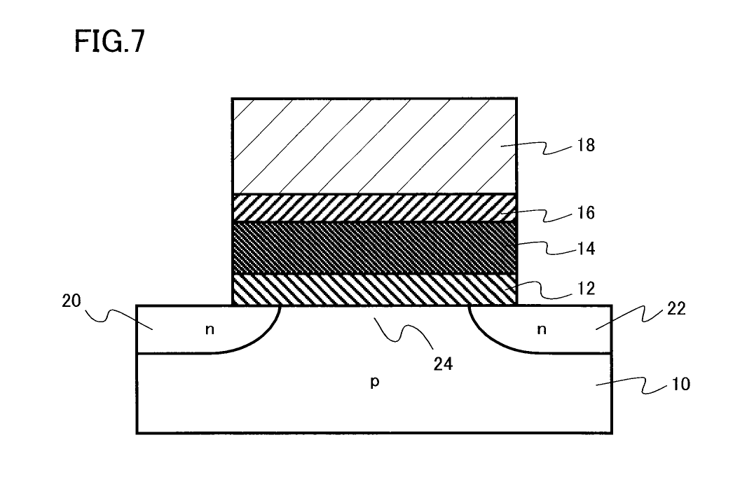

FIG. 7 is a cross-sectional view of a memory cell portion of the nonvolatile semiconductor memory device in this embodiment.

A memory cell is formed on a semiconductor layer 10 of single crystal p-type silicon containing p-type impurities, for example. The memory cell includes a tunnel insulating film 12 on the silicon semiconductor layer 10, a charge storage layer 14 on the tunnel insulating film 12, a block insulating film 16 on the charge storage layer 14, and a control gate electrode 18 on the block insulating film 16. A source region 20 and a drain region 22 are formed in the semiconductor layer 10 on opposite sides of the control gate electrode 18. A region in the semiconductor layer 10 below the control gate electrode 18 constitutes a channel region 24. The channel region 24 is interposed between the source region 20 and the drain region 22.

The source region 20 and the drain region 22 are formed by an n-type diffusion layer containing n-type impurities, for example.

In a memory cell writing operation in this embodiment, a voltage is applied between the control gate electrode 18 and the semiconductor layer 10 so that the control gate electrode 18 has a relatively positive voltage to store negative charges in the charge storage layer 14. When the control gate electrode 18 has a relatively positive voltage, an inversion layer is formed in the channel region 24 to store electrons. The electrons move through the tunnel insulating film 12 to be stored in the charge storage molecules in the charge storage layer 14.

In this state, the threshold voltage of the transistor of the memory cell is higher compared with a state where electrons are not stored. That is, it is a state where the transistor is hard to turn on. This state is a “0” state.

In a data erasing operation, a voltage is applied between the control gate electrode 18 and the semiconductor layer 10 so that the control gate electrode 18 has a relatively negative voltage. An electric field between the control gate electrode 18 and the semiconductor layer 10 causes electrons stored in the charge storage layer 14 to move through the tunnel insulating film 12 to be pulled out into the semiconductor layer 10.

In this state, the threshold voltage of the transistor of the memory cell is lower compared with the data “0” state. That is, it is a state where the transistor is easy to turn on. This state is data “1” state.

When data is read, a voltage is applied between the source region 20 and the drain region 22. For example, in the data “0” state, the threshold voltage of the transistor is high, so that an inversion layer is not formed in the channel region 24 and current does not flow between the source and the drain.

On the other hand, in an erased state, that is, the data “1” state where charges are not stored, the threshold voltage of the transistor is low, so that an inversion layer is formed in the channel region 24 and current flows between the source and the drain. Thus, by detecting the amount of current of the transistor, it can be read whether it is data “0” or data “1”.

In a data verification for verifying whether writing has been sufficiently done or not after the data writing operation, an operation similar to that in the reading operation is performed. A voltage is applied between the source region 20 and the drain region 22. When a desired current does not flow, the data writing operation is performed again.

The writing, erasing, and reading operations of the memory cell in this embodiment are performed as above for the function as a nonvolatile semiconductor memory device.

Also in this embodiment, as in the first embodiment, by using the charge storage molecules 25 having the molecular structure of the molecular formula (1) or the molecular formula (2) for the charge storage layer 14, a nonvolatile semiconductor memory device having excellent charge retention characteristics can be realized.

### Fifth Embodiment

A nonvolatile semiconductor memory device in this embodiment includes a stacked body having insulating layers and control gate electrodes alternately stacked, a semiconductor layer provided in the stacked body, the semiconductor layer facing the control gate electrodes, and an organic molecular layer having organic molecules containing the molecular structure described by the above-described molecular formula (1) provided between the semiconductor layer and the control gate electrodes.

The nonvolatile semiconductor memory device in this embodiment is different from that in the first embodiment in that it is a device having a three-dimensional structure. Contents overlapping with those in the first embodiment will not be described.

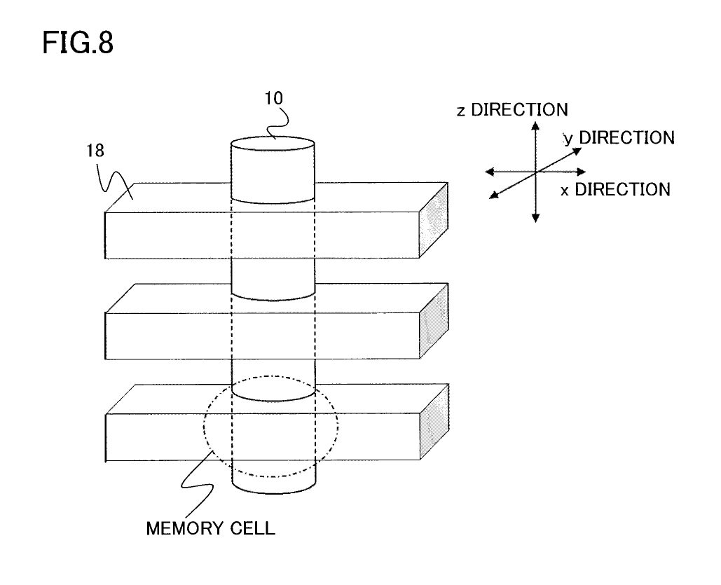

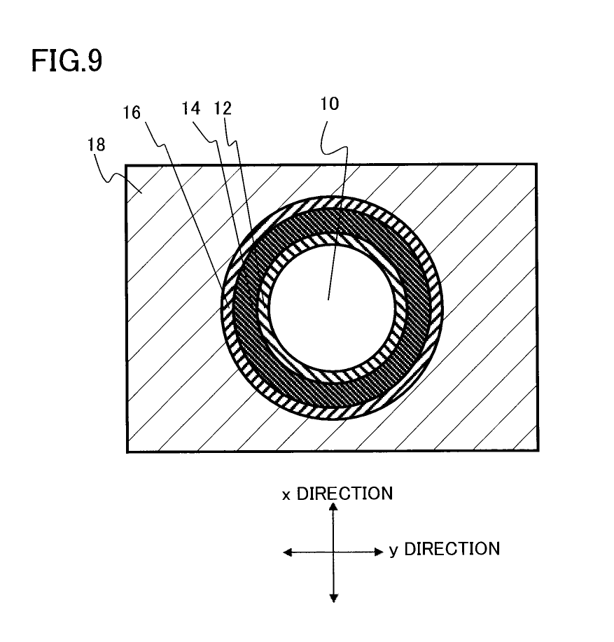

FIG. 8 is a three-dimensional conceptual diagram of the nonvolatile semiconductor memory device in this embodiment. FIG. 9 is an XY cross-sectional view of FIG. 8. FIG. 10 is an XZ cross-sectional view of FIG. 8.

The nonvolatile semiconductor memory device in this embodiment includes, for example, a stacked body 60 in which insulating layers 44 and control gate electrodes 18 are alternately stacked in layers on a silicon substrate 50.

A hole penetrating from an upper surface of the stacked body 60 to the control gate electrode 18 in the lowermost layer is provided, for example. A block insulating film 16 is provided on the side surface of the hole. A charge storage layer 14 is provided on the inner surface of the block insulating film 16.

A tunnel insulating film 12 is provided on the inner surface of the charge storage layer 14. A columnar semiconductor layer 10 is formed on the inner surface of the tunnel insulating film 12. The semiconductor layer 10 does not necessarily need to be a column, and may be a film, for example.

In other words, the semiconductor layer 10 provided opposite to the control gate electrodes 18 is provided. The tunnel insulating film 12, the charge storage layer 14, and the block insulating film 16 are provided between the semiconductor layer 10 and the control gate electrodes 18.

In FIGS. 8 and 10, a region enclosed by a broken line is a single memory cell. The structure of the memory cell is a structure in which the tunnel insulating film 12, the charge storage layer 14, and the block insulating film 16 are formed between the semiconductor layer 10 and the control gate electrode 18.

Charge storage molecules 25 in the charge storage layer 14 may be chemically bonded to either of the semiconductor layer 10 side and the control gate electrode 18 side via a substituent X as a linker in the molecular formula (1). For example, the charge storage molecules 25 may be configured to be chemically bonded to the tunnel insulating film 12 by a linker. Alternatively, for example, the charge storage molecules 25 may be configured to be chemically bonded to the block insulating film 16 by a linker.

The three-dimensional structure in this embodiment can be manufactured by using a known method of manufacturing a three-dimensional structure nonvolatile semiconductor memory device.

The nonvolatile semiconductor memory device in this embodiment improves charge retention characteristics by using the charge storage molecules 25 having the molecular structure of the molecular formula (1) or the molecular formula (2) for the charge storage layer 14. Further, according to this embodiment, by making memory cells three-dimensional, the density of the memory cells can be increased, and a nonvolatile semiconductor memory device having still higher density than those in the first to fourth embodiments can be realized.

### Sixth Embodiment

A nonvolatile semiconductor memory device in this embodiment is different from that in the fifth embodiment in that block insulating film is formed between insulating layer and control gate electrode. Contents overlapping with those in the fifth embodiment will not be described.

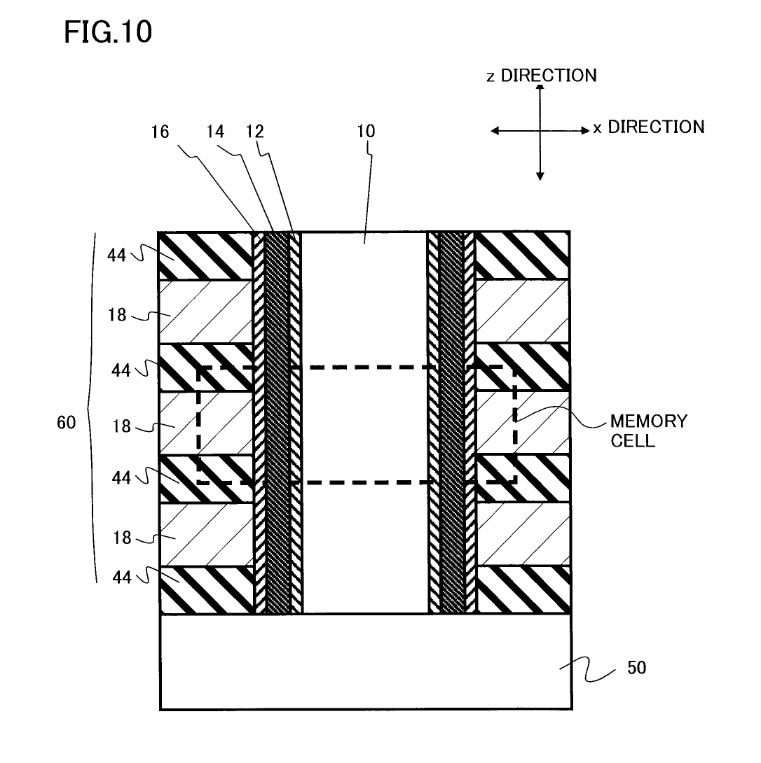

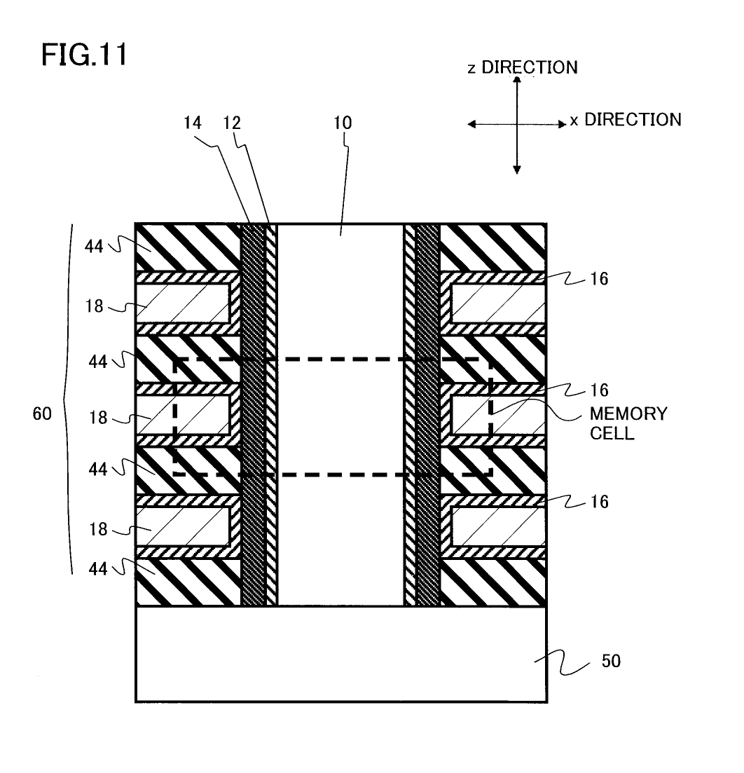

FIG. 11 is an XZ cross-sectional view of the nonvolatile semiconductor memory device in this embodiment. FIG. 11 corresponds to FIG. 10 of the fifth embodiment.

In this embodiment, block insulating film 16 is formed between insulating layer 44 and control gate electrode 18. In other words, the block insulating film 16 is formed along a surface of the control gate electrode 18.

The nonvolatile semiconductor memory device in this embodiment improves charge retention characteristics by using the charge storage molecules 25 having the molecular structure of the molecular formula (1) or the molecular formula (2) for the charge storage layer 14. Further, according to this embodiment, by making memory cells three-dimensional, the density of the memory cells can be increased, and a nonvolatile semiconductor memory device having still higher density than those in the first to fourth embodiments can be realized.

### EXAMPLES

Hereinafter, examples will be described.

### Example 1

A film configuration corresponding to that in the first embodiment was produced for evaluation.

A two-terminal device was produced by the following method, using a p-type silicon substrate. By measuring capacitance-voltage (C-V) characteristics before and after applying a pulse voltage to write date to the device, the amount of charges stored can be determined. And by measuring time dependence of C-V characteristics, the retention property of the device can be determined.

The p-type silicon substrate was introduced into a thermal oxidation furnace to form a silicon oxide film on the surface. The thickness of the silicon oxide film was about 3 nm from the result of a film thickness measurement. An aluminum oxide (Al₂O₃) film was formed on the substrate using ALD by about 0.1 nm (by one cycle process in ALD). The aluminum oxide layer depends on the type of the substituent X of the charge storage molecules 25, and is used for controlling the amount of adsorption. In this example, a porphyrin derivative (V=0 substance) having vanadium oxide at the center and phosphonic acid as the substituent X was used as a charge storage molecule.

Next, the surface of the substrate was irradiated and cleaned by a UV cleaner for ten minutes. The cleaned substrate was immersed in a toluene-ethanol mixed solution (a mixture ratio of 1:1) in which the V=0 substance at a concentration of 0.5 mM was dissolved, and the substrate was kept in that solution overnight.

When the dipole moment of the V=0 substance was determined by a molecular orbital calculation (base set B3LYP/6-31G (d)), the dipole moment of the entire molecule was calculated as 2.71, and the dipole moment in a direction perpendicular to the porphyrin ring as 2.02.

Thereafter, the substrate was taken out, moved into an unused toluene-ethanol solution, and rinsed by an ultrasonic cleaner for one minute. The rinsing operation with toluene was repeated twice, with the mixed solution being replaced with a new one.

Further, the rinsed substrate was moved into an ethanol solution, rinsed by an ultrasonic cleaner for one minute, and dried by a nitrogen air duster.

Next, the substrate was introduced into a thermal-type ALD apparatus to form a hafnium oxide film at 150° C. on the surface to which the V=0 substance had been adsorbed. As a result of a film thickness measurement, the film thickness of the hafnium oxide was about 20 nm.

Then, the rear surface of the substrate was immersed into a dense hydrofluoric acid aqueous solution to remove a native Silicon oxide film formed on the rear surface, and rinsed by pure water. Thereafter, aluminum was evaporated onto the rear surface to form an electrode on the substrate side. Onto the upper surface of the hafnium oxide of the substrate, gold was evaporated through a metal mask with holes to form a control gate electrode. Finally, it was introduced in a rapid thermal annealing (RTA) apparatus and annealed under a N₂ gas atmosphere in which 3% H₂ was mixed, at 300° C. for thirty minutes, to form a two-terminal device.

### Example 2

A four-terminal transistor device corresponding to that in the fourth embodiment was produced for evaluation. The film configuration was identical to that in Example 1.

A p-type silicon substrate was patterned with a photoresist, and subjected to phosphorus ion implantation to form an n-type channel region. Next, a tunnel film of a silicon oxide was formed on the silicon substrate in a thermal oxidation furnace. The film thickness of the oxide silicon was about 5 nm from the result of a film thickness measurement. An aluminum oxide (Al₂O₃) film was formed on the substrate using ALD by about 0.1 nm (by one cycle by ALD).

Next, the surface of the substrate was irradiated and cleaned by a UV cleaner for ten minutes. The cleaned substrate was put into a toluene-ethanol mixed solution (a mixture ratio of 1:1) in which molecules used in Example 1 were dissolved at a concentration of 0.5 mM, and placed stationarily for twenty-four hours.

Thereafter, the substrate was taken out, moved into an unused toluene-ethanol solution, and rinsed by an ultrasonic cleaner for one minute. The rinsing operation with toluene was repeated twice, with the mixed solution being replaced with a new one.

Further, the rinsed substrate was moved into an ethanol solution, rinsed by an ultrasonic cleaning machine for one minute, and dried by a nitrogen air duster.

Next, the substrate was introduced into a thermal-type ALD apparatus to forma hafnium oxide film at 150° C. on the surface to which the V=0 substance had been adsorbed. As a result of a film thickness measurement, the film thickness of the hafnium oxide was about 10 nm.

Next, it is introduced into an RTA apparatus, annealed under a N₂ gas atmosphere in which 3% H₂ was mixed, at 300° C. for thirty minutes. Then nickel was deposited on the hafnium oxide by about 100 nm by an electron beam (EB) vapor deposition apparatus. The evaporated nickel film was patterned with a photoresist to form a gate electrode.

Next, source and drain regions to be connected to the channel region were patterned with a photoresist, wet etched with buffered hydrofluoric acid to expose the silicon oxide. Aluminum was evaporated onto the surface by about 100 nm to form source and drain electrodes. The rear surface of the substrate was wet etched with hydrofluoric acid and cleaned. Aluminum was evaporated thereon by about 200 nm to form a substrate electrode. Thus the transistor device including four terminals, a gate, a source, a drain, and a substrate, was formed.

### Comparative Example 1

As in Example 1, a film configuration corresponding to that in the first embodiment was produced for evaluation. However, in place of the V=0 substance that is a charge storage molecule in Example 1, a zinc porphyrin derivative (Zn substance) having the same molecular structure except that the center metal was zinc was used. It is identical to that in Example 1 except for the type of charge storage molecules, and thus will not be described. When the dipole moment of the Zn substance was determined by a molecular orbital calculation (base set B3LYP/6-31G(d)), the dipole moment of the entire molecule was calculated as 3.77, and the dipole moment in a direction perpendicular to a porphyrin ring as 0.0.

### Comparative Example 2

As in Example 1 and Comparative Example 1, a film configuration corresponding to that in the first embodiment was produced for evaluation. However, in the Zn substance structure used in Comparative Example 1, a substituent attached to Ar₂ attached to a porphyrin ring was replaced with a high electron-withdrawing group to form a zinc porphyrin derivative (E-Zn substance) in which a dipole in a direction parallel to a porphyrin ring plane was increased. It is identical to that in Example 1 except for the type of charge storage molecules, and thus will not be described. When the dipole moment of the E-Zn substance was determined by a molecular orbital calculation (base set B3LYP/6-31G (d)), the dipole moment of the entire molecule was calculated as 6.89, and the dipole moment in a direction perpendicular to a porphyrin ring as 0.0.

### Comparative Example 3

As in Example 2, a four-terminal transistor device corresponding to that in the fourth embodiment was produced for evaluation. However, molecules used in Comparative Example 1 were used as charge storage molecules. It was identical to that in Example 1 except for the type of the charge storage molecules, and thus will not be described.

The aluminum electrode on the rear surface of the device in each of Example 1 and Comparative Examples 1 and 2 was brought into contact with a stage of a measurement apparatus to obtain a terminal, and a needle probe was put on the gold electrode on the top surface to obtain a terminal to apply a voltage. Capacitance measurement was performed at various voltages on each device, and then a pulse voltage was applied to charge the device.

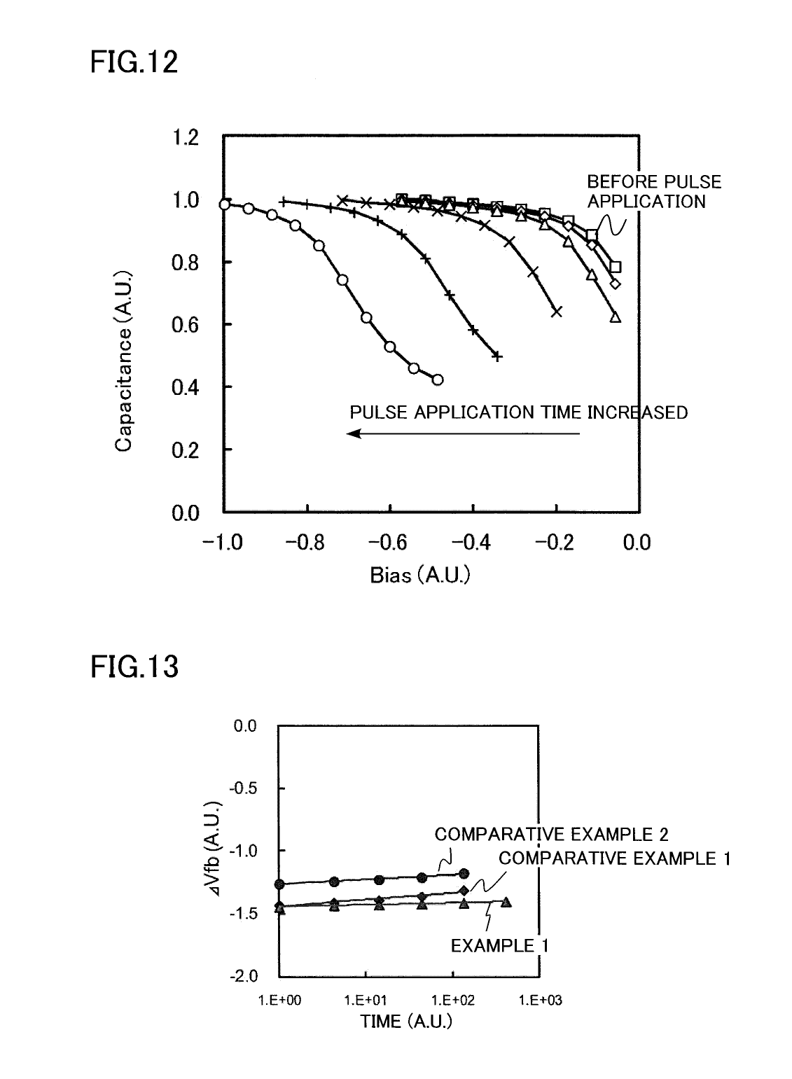

FIG. 12 is a graph showing the results of the capacitance measurement of Example 1. It is a graph in which the results of capacitance measurement performed on the device in Example 1 each time pulse application time was changed sequentially from 100 μs to is with the voltage fixed at −14 V are applied to the gold gate electrode.

A saturated region of capacitance is shown, and it was confirmed that the threshold voltage shifted in a negative direction as the pulse application time was increased. This voltage shift indicates that the pulse voltage applied from the gold gate electrode causes positive charges (holes) to move from the p-type silicon substrate to the charge storage layer, and the positive charges are stored in the charge storage layer.

Next, stored charge retention characteristics were measured on Example 1 and Comparative Examples 1 and 2. The retention characteristics were evaluated by measuring time-dependence of the C-V characteristics by first performing a capacitance measurement immediately after the application of a write pulse to the device, and then performing a capacitance measurement again after leaving it for a fixed period of time.

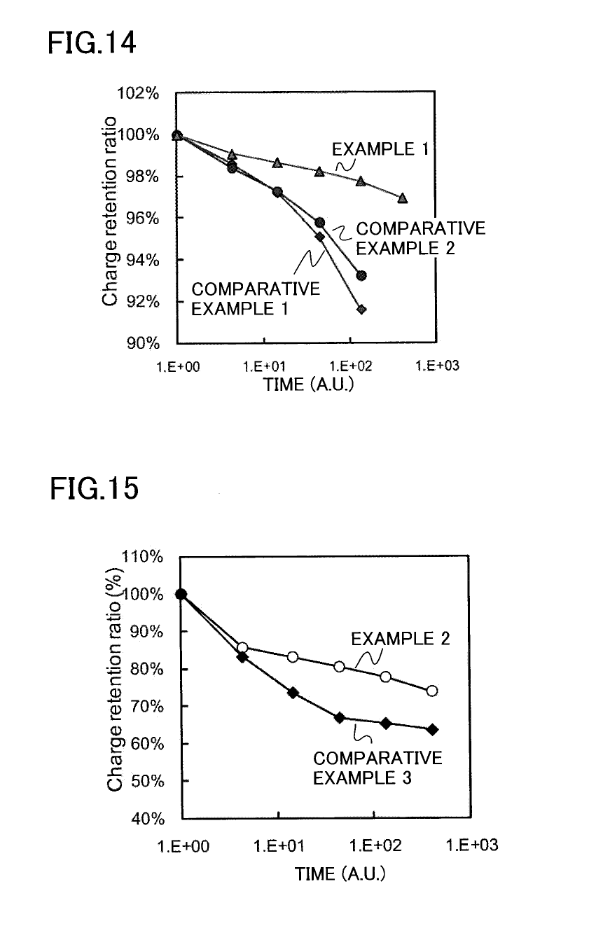

FIG. 13 is a graph showing charge retention characteristics in Example 1, Comparative Example 1, and Comparative Example 2. FIG. 14 is a graph showing charge retention ratios in Example 1, Comparative Example 1, and Comparative Example 2.

Temporal decay of the amount of stored charges was evaluated by applying a controlled pulse voltage to the gold control gate electrode so that the stored charge densities in the devices are almost equal, and determining time-dependent changes of a value of the flat-band voltage (V_{fb}) of the C-V curves shifted by the storage of positive charges by performing a capacitance measurement again after a lapse of a fixed period of time to determine the flat-band voltage of the device.

FIG. 13 is a graph in which in which the each ΔV_{fb} of retained charges is plotted with respect to time. The ΔV_{fb} is the difference between the V_{fb} which is calculated by C-V curve at certain period of time and the initial (before writing) V_{fb}. An approximate line was drawn logarithmically on plotted dots to determine the time until 5% decay relative to an initial V_{fb} value measured immediately after the write pulse application. FIG. 14 is a graph in which the ratios of stored charges are plotted relative to elapsed time.

The time until the threshold voltage (ΔV_{fb}) decays 5% in Example 1 is about 4600 times compared with Comparative Example 1, and about 1300 times compared with Comparative Example 2. It was found that Example 1 had superior charge retention characteristics. Specifically, it was found that the direction of a dipole as well as the magnitude of a dipole had an effect on the stored charge retention characteristics, and by the charge storage molecules having a dipole moment in a direction perpendicular to the porphyrin ring as in Example 1, the charge retention characteristics were improved.

FIG. 15 is a graph showing the charge retention ratios in Example 2 and Comparative Example 3. Writing was performed by applying pulse bias (−14V, pulse width: 100 msec) to the gate electrodes of the respective transistor devices in Example 2 and Comparative Example 3. The resulting threshold voltage shifts were read and followed relative to elapsed time. Reading was performed by reading a drain current obtained by applying a source-drain voltage of 0.1 V constantly and applying a gate voltage between −3 V to 3 V. A voltage at which a drain current of 1×10⁻⁷ A flowed was set as a threshold voltage.

It was found that the charge retention time in Example 2 was longer than that in Comparative Example 3 and superior.

Substances with chloroaluminum (Cl—Al) or titanyloxide (Ti═O) as center metals having a large dipole moment in a direction perpendicular to a porphyrin ring likewise provide charge retention characteristics superior to those in the comparative examples.

Although the embodiments have been described with the case where an organic molecule (charge storage molecule) is adsorbed to the semiconductor layer side via a substituent X as an example, a structure in which an organic molecule (charge storage molecule) is adsorbed to the control gate electrode side via a substituent X is also possible.

While certain embodiments have been described, these embodiments have been presented by way of example only, and are not intended to limit the scope of the inventions. Indeed, the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor layer;
an control gate electrode; and
an organic molecular layer provided between the semiconductor layer and the control gate electrode, the organic molecular layer having an organic molecule including a molecular structure described by a molecular formula (1): 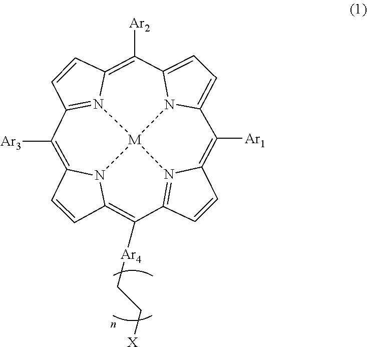
wherein M is oxymetal or chlorometal, Ar₁ to Ar₄ are each independently selected from among hydrogen, carbon, fluorine, a phenyl group, a phenyl halide group, an alkylphenyl group, an alkoxyphenyl group, a nitrated phenyl group, and a phenyl cyanide group, X is selected from among a silyl group, a phosphoryl group, a selenide group, a telluride group, an isocyanate group, an alkyl bromide group, an alkoxy group, and an ether group, and n is an integer more than or equal to zero.

2. The device according to claim 1, wherein the organic molecule is chemically bonded to a semiconductor layer side or a control gate electrode side via a substituent X in the molecular formula (1).

3. The device according to claim 1, wherein the organic molecular layer is a monomolecular film.

4. The device according to claim 1, wherein M in the molecular formula (1) is oxovanadium, oxytitanium, or chloroaluminum.

5. The device according to claim 1, further comprising a block insulating film provided between the organic molecular layer and the control gate electrode.

6. The device according to claim 1, further comprising a tunnel insulating film provided between the semiconductor layer and the organic molecular layer.

7. The device according to claim 1, wherein Ar₁ and Ar₃ in the molecular formula (1) are identical substituents.

8. A semiconductor memory device comprising:
a semiconductor layer;
a control gate electrode; and
an organic molecular layer provided between the semiconductor layer and the control gate electrode, the organic molecular layer having an organic molecule including a molecular structure described by a molecular formula (2): 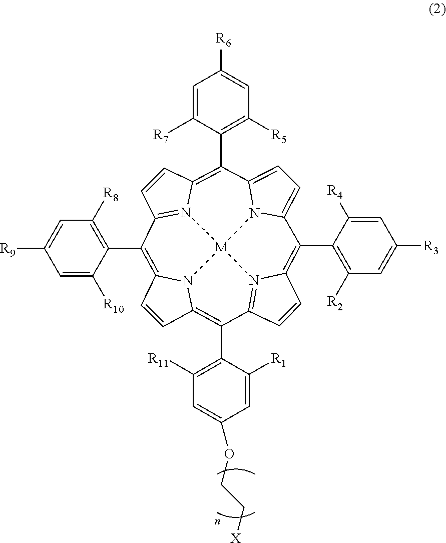
wherein M is oxymetal or chlorometal, R₁ to R₁₁ are each independently selected from hydrogen, a methyl group, halogen, an alkoxy group, a carboxy group, a cyano group, and a nitro group, X is selected from among a silyl group, a phosphoryl group, a selenide group, a telluride group, an isocyanate group, an alkyl bromide group, an alkoxy group, and an ether group, and n is an integer more than or equal to zero.

9. The device according to claim 8, wherein the organic molecule is chemically bonded to a semiconductor layer side or a control gate electrode side via a substituent X in the molecular formula (2).

10. The device according to claim 8, wherein the organic molecular layer is a monomolecular film.

11. The device according to claim 8, wherein M in the molecular formula (2) is oxovanadium, oxytitanium, or chloroaluminum.

12. The device according to claim 8, further comprising a block insulating film provided between the organic molecular layer and the control gate electrode.

13. The device according to claim 8, further comprising a tunnel insulating film provided between the semiconductor layer and the organic molecular layer.

14. A semiconductor memory device comprising:
a stacked body having insulating layers and control gate electrodes alternately stacked;
a semiconductor layer provided in the stacked body, the semiconductor layer facing the control gate electrodes; and
an organic molecular layer provided between the semiconductor layer and one of the control gate electrodes, the organic molecular layer having an organic molecule including containing a molecular structure described by a molecular formula (1): 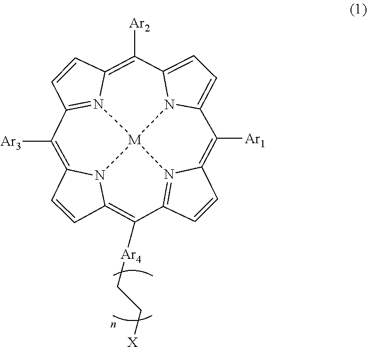
wherein M is oxymetal or chlorometal, Ar₁ to Ar₄ are each independently selected from among hydrogen, carbon, fluorine, a phenyl group, a phenyl halide group, an alkylphenyl group, an alkoxyphenyl group, a nitrated phenyl group, and a phenyl cyanide group, X is selected from among a silyl group, a phosphoryl group, a selenide group, a telluride group, an isocyanate group, an alkyl bromide group, an alkoxy group, and an ether group, and n is an integer more than or equal to zero.

15. The device according to claim 14, wherein the organic molecule is chemically bonded to a semiconductor layer side or a control gate electrode side via a substituent X.

16. The device according to claim 14, wherein the organic molecular layer is a monomolecular film.

17. The device according to claim 14, wherein M in the molecular formula (1) is oxovanadium, oxytitanium, or chloroaluminum.

18. The device according to claim 14, further comprising a block insulating film provided between the organic molecular layer and the control gate electrodes.

19. The device according to claim 14, further comprising a tunnel insulating film provided between the semiconductor layer and the organic molecular layer.

20. The device according to claim 14, wherein Ar₁ and Ar₃ in the molecular formula (1) are identical substituents.
